(19) United States
(12) Patent Application Publication
(10) Pub. No.: US 2025/0029829 A1
(43) Pub. Date: Jan. 23, 2025

(54) SUBSTRATE PROCESSING METHOD

(71) Applicant: ASM IP Holding B.V., Almere (NL)

(72) Inventors: SungBae Kim, Yongin-si (KR); Sungdae Woo, Hwaseong-si (KR); JuSeok Jeon, Yangju-si (KR); SeungRyul Lee, Seoul (KR); Hyunchul Kim, Hwaseong-si (KR); Yujin Kim, Hwaseong-Si (KR)

(21) Appl. No.: 18/770,973

(22) Filed: Jul. 12, 2024

Related U.S. Application Data
(60) Provisional application No. 63/527,139, filed on Jul. 17, 2023.

(51) Int. Cl. H01L 21/02; C23C 16/34; C23C 16/44; C23C 16/455; C23C 16/56; H01J 37/32; H01L 21/033

(52) U.S. Cl. CPC H01L 21/02186; C23C 16/34; C23C 16/4408; C23C 16/45538; C23C 16/56; H01J 37/32183; H01J 37/3244; H01L 21/02205; H01L 21/0337; H01J 2237/332

(57) ABSTRACT

Provided is a substrate processing method using a PEALD method in which an amorphous TiN film is formed on the substrate. The substrate processing method comprises providing the substrate to a reaction chamber, supplying a first gas to the reaction chamber, supplying a second gas to the reaction chamber, and applying a power to the reaction chamber, wherein a frequency of the power is a variable frequency, wherein the second gas is activated by the power.

### CROSS-REFERENCE TO RELATED APPLICATIONS

This application claims priority to U.S. Provisional Patent Application Ser. No. 63/527,139 filed Jul. 17, 2023 titled SUBSTRATE PROCESSING METHOD, the disclosure of which is hereby incorporated by reference in its entirety.

### FIELD OF INVENTION

The disclosure relates to forming a semiconductor film on a substrate, particularly to a method of forming a titanium nitride (TiN) spacer film on a pattern structure.

### BACKGROUND OF THE DISCLOSURE

As the size of semiconductor devices continues to shrink, a line width of the device circuit narrows. Therefore, technical difficulties to form a spacer film on the patterns increase. To overcome that problem, a DPT (Double Patterning Technology) process is employed. In an existing DPT process, a SiO₂ film is formed as a spacer film on the pattern. However, as the line width becomes narrower, a new spacer film with higher selectivity than the existing SiO₂ film on the pattern is required.

A TiN film is introduced as a spacer film instead of SiO₂ film and the film is required to have low impurity to achieve high selectivity. To that end, the TiN film is formed at a high temperature over 300° C. and exposed to a plasma for a long time to remove impurities (such as carbon and oxygen, for example) by an ion bombardment. However, the process conditions result in a crystalline TiN film and a damage to the sublayer such as hard mask. A crystalline TiN film has a strong bonding structure, resulting in difficulties removing impurities therefrom. An exposure of the reactor to a plasma for a long time may cause an increase of temperature in a reactor due to continuous ion bombardment to the reactor and lead to a deterioration of a film quality in subsequent processes. Thus, a method of forming a TiN film to avoid the aforementioned problems is desired.

### SUMMARY OF THE DISCLOSURE

The disclosure discloses a method of forming a film on a pattern, particularly an amorphous TiN film with low impurities as a spacer film on a pattern.

In one or more embodiments, a method of forming a film on a pattern substrate, the method may comprise the steps of providing the substrate to a reaction chamber, supplying a first gas to the reaction chamber, supplying a second gas to the reaction chamber, and applying a power to the reaction chamber, wherein a frequency of the power may be a variable frequency and the second gas may be activated by the power.

In one or more embodiments, the film may comprise an amorphous TiN with impurities of 25% or less.

In one or more embodiments, the impurities may comprise at least one of an oxygen, a carbon, or a mixture thereof.

In one or more embodiments, a reflect power of 5W or less is generated during applying the power to the reaction chamber.

In one or more embodiments, the first gas may comprise at least one of tetrakis-dimethylamino titanium (Ti[N(CH₃)₂]₄, TDMAT), tetrakis-diethylamido titanium, ([(C₂H₅)₂N]₄Ti, TDEAT), tetrakis-ethylmethylamino titanium (Ti[(CH₃C₂H₅)N]₄, TEMAT), titanium isopropoxide (Ti[OCH(CH₃)₂], TTIP), titanium chloride (TiCl₄), a derivative thereof, or a mixture thereof.

In one or more embodiments, the second gas comprises at least one of N₂, NH₃, NH₄, N₂H₂, N₂H₄, or a mixture thereof.

In one or more embodiments, the method further comprises supplying a third gas to the reaction chamber and activating the second gas and the third gas simultaneously by the power.

In one or more embodiments, the method may further comprise treating the film by supplying a third gas to the reaction chamber and activating the third gas by the power, after forming a film by supplying the first gas, supplying the second gas and activating the second gas by the power.

In one or more embodiments, the third gas comprises at least one of a hydrogen, an atomic hydrogen, or a mixture thereof.

In one or more embodiments, the method of forming the film is carried out at between about 100° C. and about 250° C., or between about 150° C. and about 200°° C.

In one or more embodiments, the power of between about 200W and about 500W, or between about 250W and about 450W is applied to the reaction chamber.

In one or more embodiments, a method of patterning a substrate may comprise the steps of providing a substrate to a reaction chamber, forming a first film on the substrate, forming a second film on the first film, patterning the second film, forming a third film on the second film, removing the third film selectively, removing the second film, removing the first film selectively and removing the third film, wherein the third film is an amorphous TiN.

In one or more embodiment, the first film may comprise an amorphous carbon and the second film may comprise an amorphous silicon.

In one or more embodiments, removing the third film selectively is carried out by an etch back.

In one or more embodiments, removing the second film and removing the first film selectively are carried out by a selective etching.

In one or more embodiments, removing the third film is carried out by at least one of ashing and strip.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIG. 1 illustrates a substrate processing method according to one embodiment of the disclosure.

FIG. 2 illustrates a substrate processing method according to another embodiment of the disclosure.

FIG. 3A and FIG. 3B illustrate timing charts of the substate processing methods according to the disclosure.

FIG. 4A and FIG. 4B illustrate plasma processes and matching times according to the type of impedance matching.

FIG. 5A and FIG. 5B show RF power patterns when the VF (Variable Frequency) mode is off (i.e. fixed frequency mode in a conventional process) and on (i.e. variable frequency mode in the embodiment of the disclosure).

FIG. 6A and FIG. 6B show an XRD data showing a crystalline TiN film and the amounts of impurities such as carbon and oxygen respectively.

FIG. 7A and FIG. 7B show an XRD data showing an amorphous TiN film and the amounts of impurities such as carbon and oxygen respectively.

FIG. 8 illustrates a patterning process to which a TiN spacer film may be formed according to the disclosure.

FIG. 9A illustrates film thickness differences between batches and between reaction chambers in the same batch at fixed frequency mode.

FIG. 9B illustrates film thickness differences between batches and between reaction chambers in the same batch at variable frequency mode.

FIG. 10 illustrates a multi-reaction chamber system according to the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

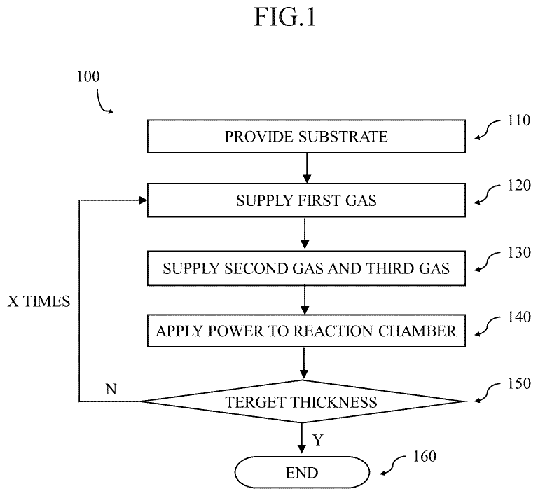

FIG. 1 illustrates a substrate processing method according to one embodiment of the disclosure.

In the step 110 of the substrate processing method 100, a substrate may be provided to a reaction chamber. The substrate may have a semiconductor circuit formed thereon including a 3D structure and a gap. The reaction chamber may comprise an equipment in which the substrate is processed. In the reaction chamber, a deposition, a gap fill, an etch, or any other substrate processing process using a plasma may be performed on the substrate.

In the step 120, a first gas may be supplied to the substrate. The first gas may comprise a titanium-containing gas. The first gas may comprise at least one of: tetrakis-dimethylamino titanium (Ti[N(CH₃)₂]₄, TDMAT), tetrakis-diethylamido titanium, ([(C₂H₅)₂N]₄Ti, TDEAT), tetrakis-ethylmethylamino titanium (Ti[(CH₃C₂H₅)N]₄, TEMAT), titanium isopropoxide (Ti[OCH(CH₃)₂], TTIP), titanium chloride (TiCl₄), a derivative thereof, or a mixture thereof.

The first gas may be adsorbed on the substrate. Although not mentioned in the substrate processing method 100, the step 120 may be followed by a purge step in order to purge the unused first gas and by-products out of the reaction chamber.

In the step 130, a second gas and a third gas may be supplied to the reaction chamber. The second gas and the third gas may be supplied simultaneously. For instance, the second gas and the third gas may be supplied continuously to the reaction chamber throughout the process. In another embodiment, the second gas may be supplied continuously and the third gas may be supplied intermittently.

The second gas may comprise a nitrogen-containing gas. The second gas may comprise at least one of: N₂, NH₃, NH₄, N₂H₂, N₂H₄, or a mixture thereof.

The third gas may comprise a hydrogen-containing gas. The third gas may comprise at least one of: a hydrogen, an atomic hydrogen, or a mixture thereof.

In the step 140, a power may be applied to the reaction chamber. The power may be a RF power and be applied to the reaction chamber in situ. In other embodiment, the power may be applied ex situ.

In one embodiment, the power of between about 200W and about 500W may be applied to the reaction chamber, or the power of between about 250W and about 450W may be applied to the reaction chamber.

The frequency of the power may not be a fixed frequency. In other words, the frequency of the power may be a variable frequency. That is, the impedance between the reaction chamber and a matching network may be matched by varying the frequency of the power by an algorithm or a firmware embedded in the power generator, not by the mechanical movements of VVCs (Vacuum Variable Capacitors) of the matching network.

In the embodiment, applying the variable frequency of RF power to the reaction chamber may result in a reflect power of 5W or less. Therefore, more efficient plasma process may be possible.

The power may be applied in order to activate the second gas in order to generate radicals of the second gas (e.g., nitrogen radicals). The activated second gas may react chemically with the first gas adsorbed on the substrate and a form a film (e.g., TiN).

The power may also activate the third gas (e.g., hydrogen radicals). The activated third gas may react chemically with the impurities existing in the film such as carbon and oxygen and assist to remove them from the film. The second gas and the third gas may be supplied and activated simultaneously.

Although not mentioned in the substrate processing method 100, the step 140 may be followed by a purge step in order to purge the unreacted second and third gas and by-products out of the reaction chamber.

In the step 150, a film thickness may be measured. If the film thickness does not reach the target thickness, then the step 120, the step 130 and the step 140 may be repeated a couple of times (X times). If the film thickness reaches the target thickness, then the process may end at a step 160. The target thickness may be set by inputting a certain number of cycles in the control system (not shown) of the reaction chamber.

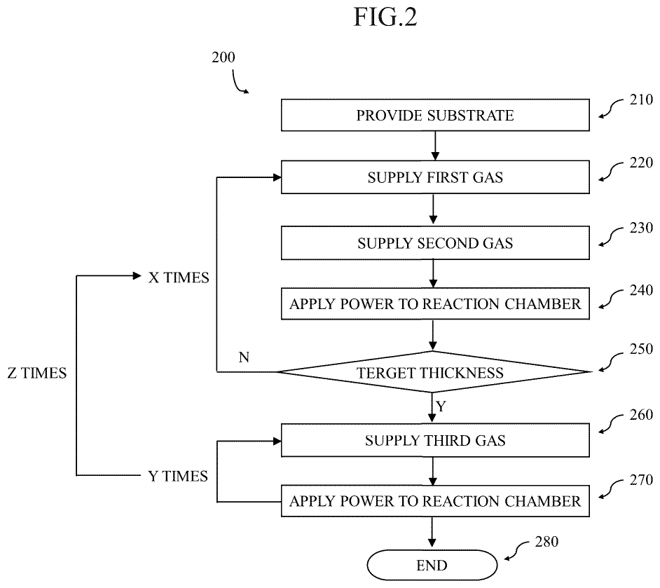

FIG. 2 illustrates a substrate processing method according to another embodiment of the disclosure.

The substrate processing method 200 may comprise a deposition step comprising the steps 220 to 240 and a treatment step comprising the steps 260 to 270.

In the step 210 of the substrate processing method 200, a substrate may be provided to a reaction chamber. The substrate may have a semiconductor circuit formed thereon such as a 3D structure and a gap.

In the step 220, a first gas may be supplied to the substrate. The first gas may comprise a titanium-containing gas as mentioned in FIG. 1. The first gas may comprise at least one of: tetrakis-dimethylamino titanium (Ti[N(CH₃)₂]₄, TDMAT), tetrakis-diethylamido titanium, ([(C₂H₅)₂N]₄Ti, TDEAT), tetrakis-ethylmethylamino titanium (Ti[(CH₃C₂H₅)N]₄, TEMAT), titanium isopropoxide (Ti[OCH(CH₃)₂], TTIP), titanium chloride (TiCl₄), a derivative thereof, or a mixture thereof.

The first gas may be adsorbed on the substrate. Although not mentioned in the substrate processing method 200, the step 220 may be followed by a purge step in order to purge the unreacted first gas and by-products out of the reaction chamber.

In the step 230, a second gas may be supplied. The second gas may comprise at least one of: N₂, NH₃, NH₄, N₂H₂, N₂H₄, or a mixture thereof. In another embodiment, the second gas may be supplied continuously throughout the deposition step.

In the step of 240, a power may be applied to the reaction chamber. The power may be a RF power and be applied to the reaction chamber in situ. In other embodiment, the power may be applied ex situ.

In one embodiment, the power of between about 200W and about 500W may be applied to the reaction chamber, or the power of between about 250W and about 450W may be applied to the reaction chamber.

The frequency of the power may not be a fixed frequency. In other words, the frequency of the power may be a variable frequency. That is, the impedance between the reaction chamber and a power generator may be matched by varying the frequency of the power coming out of the power generator (e.g., RF generator) by an algorithm or a firmware embedded in the power generator, not by the mechanical movements of VVCs (Vacuum Variable Capacitors) of the matching network.

In the embodiment, applying the variable frequency of RF power to the reaction chamber may result in a reflect power of 5W or less. Therefore, the efficiency of the plasma process may be improved.

The power may be applied in order to activate the second gas in order to generate radicals of the second gas (e.g., nitrogen radicals). The activated second gas may react chemically with the first gas adsorbed on the substrate and a form a film (e.g., TiN).

Although not mentioned in the substrate processing method 200, the step 240 may be followed by a purge step in order to purge the unreacted second gas and by-products out of the reaction chamber.

In the step 250, a film thickness may be measured. If the film thickness does not reach the target thickness, then the step 220, the step 230 and the step 240 may be repeated a couple of times (X times). If the film thickness reaches the target thickness, then the process may carry out the treatment step comprising the steps 260 and 270. The target thickness may be set by inputting a certain number of cycles in the control system (not shown) of the reaction chamber.

In the step 260, a third gas may be supplied. The third gas may comprise a hydrogen-containing gas. The third gas may comprise at least one of: a hydrogen, an atomic hydrogen, or a mixture thereof.

In the step 270, a power may be applied to the reaction chamber. The power may be a RF power and be applied to the reaction chamber in situ. In other embodiment, the power may be applied ex situ.

In one embodiment, the power of between about 200W and about 500W may be applied to the reaction chamber, or the power of between about 250W and about 450W may be applied to the reaction chamber.

The frequency of the power may not be a fixed frequency. In other words, the frequency of the power may be a variable frequency. That is, the impedance between the reaction chamber and a matching network may be matched by varying the frequency of the power by an algorithm or a firmware embedded in the power generator, not by the mechanical movements of VVCs (Vacuum Variable Capacitors) of the matching network.

In the embodiment, applying the variable frequency of RF power to the reaction chamber may result in a reflect power of 5W or less. Therefore, the efficiency of the plasma process may be improved.

The power may also activate the third gas (e.g., hydrogen radicals). The activated third gas may react chemically with the impurities existing in the film such as carbon and oxygen and assist to remove them from the film.

Although not mentioned in the substrate processing method 200, the step 270 may be followed by a purge step in order to purge the unreacted second and third gas and by-products out of the reaction chamber. The third gas may be supplied continuously throughout the treatment step.

The treatment step comprising the steps 260 and 270 may be repeated a plurality of times (Y times) and the deposition step and the treatment step may be repeated a plurality of times respectively. And a super cycle comprising the deposition step and the treatment step may be repeated a plurality of times (Z cycles).

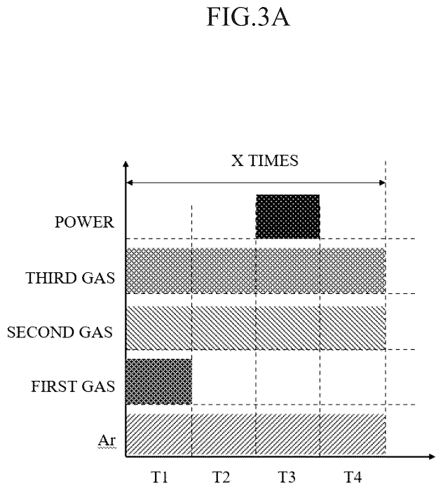

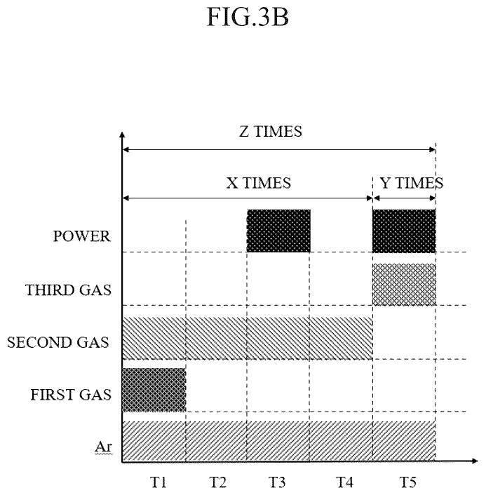

FIG. 3A illustrates a timing chart of the substate processing method according to the disclosure.

In the step T1 of FIG. 3A, a first gas may be supplied to the substrate. The first gas may comprise a titanium-containing gas. The first gas may comprise at least one of: tetrakis-dimethylamino titanium (Ti[N(CH₃)₂]₄, TDMAT), tetrakis-diethylamido titanium, ([(C₂H₅)₂N]₄Ti, TDEAT), tetrakis-ethylmethylamino titanium (Ti[(CH₃C₂H₅)N]₄, TEMAT), titanium isopropoxide (Ti[OCH(CH₃)₂], TTIP), titanium chloride (TiCl₄), a derivative thereof, or a mixture thereof.

In steps T1 to T3, a second gas and a third gas may be supplied continuously and simultaneously to the reaction chamber. The second gas may comprise a nitrogen-containing gas and the third gas may comprise a hydrogen-containing gas.

In the step T3, a power may be applied to the reaction chamber in order to activate the second gas and generate radicals of the second gas (e.g., nitrogen radicals). The activated second gas may react chemically with the first gas adsorbed on the substrate and a form a film (e.g., TiN).

In the step T3, the power may also activate the third gas (e.g., hydrogen radicals). The activated third gas may react chemically with the impurities existing in the film such as carbon and oxygen and assist to remove them from the film. The step T3 may correspond to the step 140 of FIG. 1. In another embodiment, purge steps T2 and T4 may be further added after supplying the first gas and after applying the power. The steps T1 to T4 may correspond to they step 120 to 150 of FIG. 1. The method of FIG. 3A be repeated a plurality of times (X times).

FIG. 3B illustrates a timing chart of the substate processing method according to the disclosure.

In the step T1 of FIG. 3B, a first gas may be supplied to the substrate. The first gas may comprise a titanium-containing gas. The first gas may comprise at least one of: tetrakis-dimethylamino titanium (Ti[N(CH₃)₂]₄, TDMAT), tetrakis-diethylamido titanium, ([(C₂H₅)₂N]₄Ti, TDEAT), tetrakis-ethylmethylamino titanium (Ti[(CH₃C₂H₅)N]₄, TEMAT), titanium isopropoxide (Ti[OCH(CH₃)₂], TTIP), titanium chloride (TiCl₄), a derivative thereof, or a mixture thereof. The step T1 may correspond to the step 220 of FIG. 2.

In steps T1 to T3, a second gas may be supplied continuously to the reaction chamber. The second gas may comprise a nitrogen-containing gas.

In the step T3, a power may be applied to the reaction chamber in order to activate the second gas and generate radicals of the second gas (e.g., nitrogen radicals). The activated second gas may react chemically with the first gas adsorbed on the substrate and a form a film (e.g., TiN). The steps T1 to T4 may be repeated a plurality of times (X times).

In the step T5, a third gas may be supplied to the substrate. The third gas my comprise a hydrogen-containing gas. In the step T5, a power may be applied in order to activate the third gas (e.g., hydrogen radicals). The activated third gas may react chemically with the impurities existing in the film such as carbon and oxygen and assist to remove them from the film. The step T5 may repeated a plurality of times (Y times). The steps T1 to T4 may correspond to the step 220 to 250 of FIG. 2 and the step T5 may correspond to the steps 260 to 270 of FIG. 2. A super cycle comprising a deposition step T1 to T4 and a treating step T5 may be repeated a plurality of times (Z times).

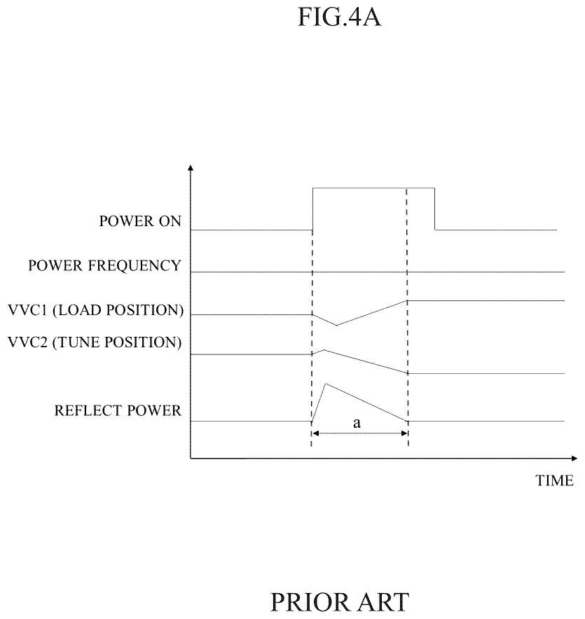

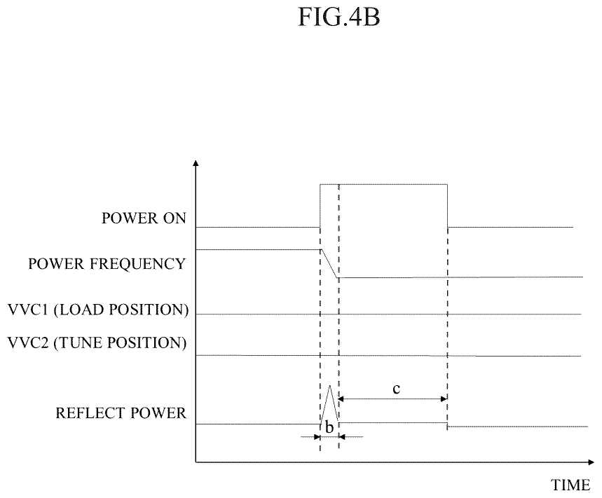

FIG. 4A and FIG. 4B illustrate plasma processes and matching times according to the type of impedance matching.

FIG. 4A illustrates a plasma process using a conventional impedance matching in which a power frequency is fixed and VVCs move. As shown in FIG. 4A, the conventional impedance matching between a power generator and a reactor may be carried out by a mechanical matching network. In a matching network, two VVCs (Vacuum Variable Capacitors) move back and forth to match the impedance between the power generator and the reactor. But the mechanical movement of the VVCs requires a period of time ‘a’ for matching and has a limitation in reducing the matching time accordingly, and usually generate a high reflected power as the plasma-on time becomes shorter.

FIG. 4B illustrates a plasma process according to the disclosure in which power frequency varies and VVCs are fixed. As shown in FIG. 4B, a variable frequency (VF) tuning may be carried out in which a frequency of the power coming out of the power generator (e.g., RF generator) may be changed, while the positions of VVCs in the matching network are fixed. The frequency tuning of the power may be conducted by controlling a firmware (software) embedded in the power generator. Since the operation is controlled by the software, the matching time ‘b’ becomes much shorter than the matching time ‘a’ shown in FIG. 4A. and the reflected power may be small compared to a conventional matching network. Therefore, a substrate process in the variable frequency mode may be much faster than in the conventional fixed frequency method.

In another embodiment, as shown in FIG. 4B, in a plasma process in variable frequency mode, 5W or less of reflect power may remain during the time ‘c’ after the matching completes.

The power frequency variation may be changed within a margin of +/−5% of the set frequency. For instance, in case of 13 MHz RF power, the range of frequency variation may be between 12.8 MHz and 14.3 MHz. In case of 27 MHz RF power, the range of frequency variation may be between 25.8 MHz and 28.5 MHZ.

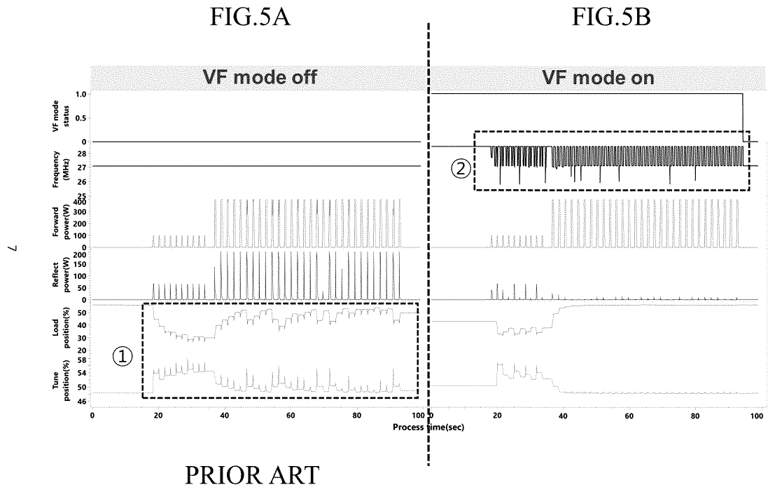

FIG. 5A shows a RF power pattern when the VF (Variable Frequency) mode is off (i.e. fixed frequency mode in a conventional process) and FIG. 5B shows a RF power pattern when the VF mode is on (i.e. variable frequency mode in the embodiment of the disclosure).

In FIG. 5A, when the substrate is processed in the VF-off mode, a 400W RF power with a frequency of 27 MHz is applied to the reaction chamber. As shown in FIG. 5A, a 400W RF power (i.e., forward power) is applied and the frequency is fixed at 27 MHz. Two VVCs (Vacuum Variable Capacitors) keep moving as denoted in \textcircled{1} in a matching network (i.e. load position and tune position) in order to match the impedance between the reaction chamber and the RF power generator.

As shown in FIG. 5A, however, a reflect power of 200W is generated. That is, about 50% of forward power applied to the reaction chamber does not contribute to the process. Therefore, in order to compensate the power loss, the RF power application time may be set to be longer and/or the high RF power may be applied, and/or the process temperature may be set to be higher.

In contrast, in FIG. 5B, when the substrate is processed in the VF-on mode according to the disclosure, a 400W RF power with a frequency of 27 MHz is applied to the reaction chamber. The frequency, however, varies between 25.8 MHz and 28.5 MHz. In another embodiment, if a frequency of 13 MHz is applied, the frequency may vary between 12.8 MHz and 14.3 MHz.

As shown in FIG. 5B, a 400W RF power (i.e. forward power) is applied and the frequency varies as denoted as \textcircled{2}. Two VVCs (Vacuum Variable Capacitors) are fixed in a matching network (i.e. load position and tune position). In other words, the impedance matching between the reaction chamber and the RF power generator may be achieved by keeping varying the frequency of the RF power, not by the mechanical movement of VVCs in the conventional matching network.

In FIG. 5B, a very small intensity of reflect power may be generated. The reflect power may be 5W or less. That is, almost all forward power applied to the reaction chamber contributes to the process. Therefore, a high plasma efficiency may be kept without setting longer RF power application time and setting higher the process temperature.

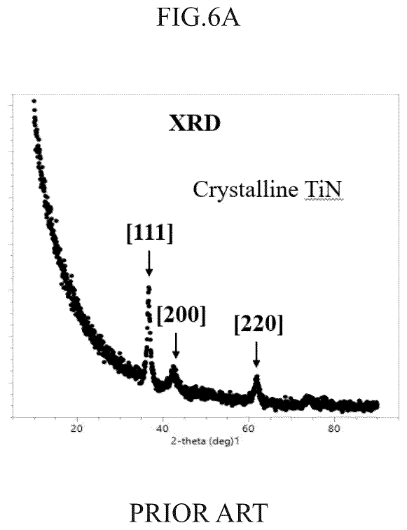

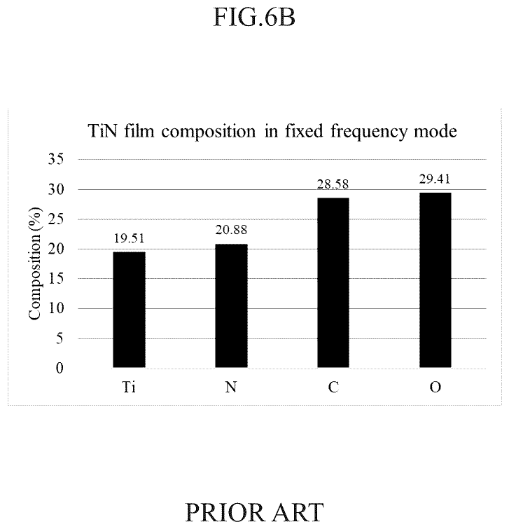

FIG. 6A and FIG. 6B show an XRD data showing a crystalline TiN film and the amounts of impurities such as carbon and oxygen respectively.

As shown in FIG. 6A, those conditions, however, may result in a crystalline TiN film in which the TiN film grows in three crystal directions [111], [200] and [220] denoted by peaks at 20=approximately 37, 43 and 63 degrees respectively. The TiN crystalline film with strong bonding structure due to longer RF time and higher process temperature may make it difficult to remove impurities such as carbon and oxygen from the film.

As shown in FIG. 6B, the TiN film formed in conventional fixed frequency mode may produce over 28% of carbon and oxygen impurities, close to 30%. The high amounts of impurities may lead to a non-uniform spacing between patterns in a patterning process such as DPT process and may cause defects in the subsequent processes.

The plasma process in the VF-on mode may have a faster matching response time and greater RF power efficiency than the plasma process in the VF-off mode. For instance, an amorphous TiN film with lower impurities may be formed at low temperature as a result (e.g., between about 100° C. and about 250° C., or between about 150° C. and about 200°° C.), resulting in amorphous TiN film properties.

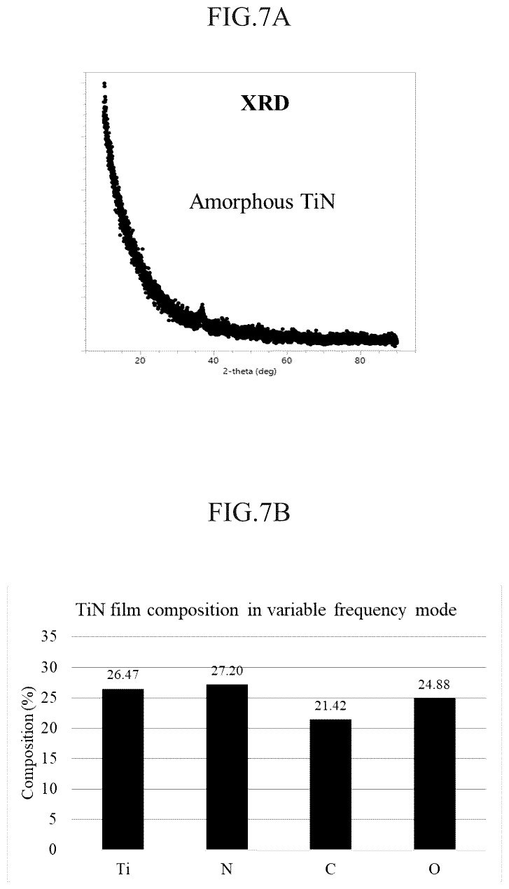

FIG. 7A and FIG. 7B show an XRD data showing an amorphous TiN film and the amounts of impurities such as carbon and oxygen respectively.

FIG. 7A shows that the TiN film formed in the variable frequency mode (VF-on mode) may be amorphous. Such is illustrated by a lack of peaks like those shown in FIG. 6A.

FIG. 7B shows that the TiN film formed in variable frequency mode may produce 25% or less of carbon and oxygen impurities, lower than that of TiN film formed in the fixed frequency mode as shown in FIG. 6B. In other words, the portions of Ti and N in the film may be relatively high, in particular higher than those percentages achieved through the prior art process illustrated in FIG. 6B.

In the VF-on mode, a short RF application time and a low process temperature may enable to form an amorphous TiN film with relatively weak bonding structure compared to a crystalline TiN film. Therefore, the weak bonding structure facilitates the reaction between the activated third gas and the impurities and the removal of the impurities from the TiN film.

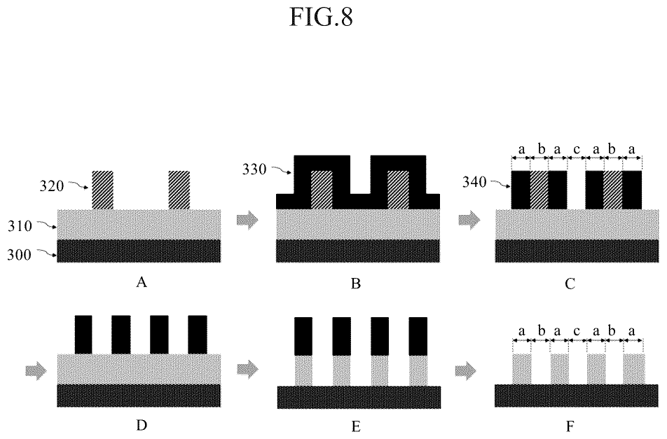

Table 1 shows process conditions for forming the third film 330 of FIG. 8 (i.e. TiN film) according to one embodiment of the disclosure.

TABLE 1
process conditions for forming the TiN film
according to one embodiment of the disclosure

| | | Process conditions |
|---|---|---|
| Gas flow rate | Source carrier | 500 to 2,000 (preferably 1,000 to |
| (sccm) | Ar | 1,500) |
| | Purga Ar | 1,000 to 10,000 (preferably 3,000 to |
| | | 8,000) |
| | N₂ | 100 to 1,000 (preferably 400 to 800) |
| | H₂ | 100 to 1,000 (preferably 400 to 800) |
| Process time per | Source feeding | 0.2 to 1.0 (preferably 0.4 to 0.8) |
| step (second) | Purge | 0.2 to 1.0 (preferably 0.4 to 0.8) |
| | RF-ON | 1.0 to 3.0 (preferably 1.5 to 2.5) |
| | Purge | 1.0 to 3.0 (preferably 1.5 to 2.5) |
| RF conditions | RF power (W) | 200 to 500 (preferably 250 to 450) |
| | RF frequency | 13 to 30 |
| | (MHz) | |
| | RF frequency | Variable frequency mode |
| | mode | |

| | |
|---|---|
| Process temperature (° C.) | 100 to 250 (preferably 150 to 200) |
| Titanium source | amino/amido titanium |

FIG. 8 illustrates a patterning process to which a TiN spacer film may be formed according to the disclosure. The patterning process may be a double patterning technology (DPT) process.

In step A of FIG. 8, a first film 310 may be formed as a hardmask on the substrate 300, followed by forming a second film 320 and patterning the second film 320. The second film 320 may be a mandrel patterned on the first film 310. The first film may comprise a carbon-containing material such as amorphous carbon and the second film may comprise a silicon-containing material such as amorphous silicon.

In step B, a third film 330 may be formed as a spacer film conformally on the second film 320. The third film 330 may comprise a titanium-containing material such as amorphous TiN film formed by PEALD method according to FIG. 1, FIG. 2, FIG. 3A, and FIG. 3B of the disclosure. In forming the third film 330, a variable frequency RF power may be applied to a reaction chamber, resulting in the third film being amorphous.

In step C, the third film 330 formed in the direction perpendicular to the etching gas supplying toward the substrate may be selectively removed. In other words, portions of the third film 330 formed on the top of the second film 320 and portions of the third film 330 formed on the first film 310 between the second films 320 may be removed. That may result in equal thicknesses and spacing between the second film 320 and the third film 340 (i.e., a=b=c). Therefore, the third film 340 formed on the side wall of the second film 320 may remain. In one embodiment, an etch back process may be carried out to remove the third film 340 selectively.

In step D, the second film 320 (i.e., a mandrel) may be removed selectively, while leaving the third film 340 intact. In one embodiment, a wet etch process may be carried out to remove the second film 320 selectively.

In step E, the first film 310 (i.e., a hardmask) may be further removed selectively, while leaving the third film 340 intact. In one embodiment, a wet etch process may be carried out to remove the first film 310 selectively.

In step F, the remaining third film 340 may be removed. That may result in the same spacing between the remaining first film 310 (i.e., a=b=c). In one embodiment, an ashing or a strip process may be carried out to remove the third film 340.

The disclosure may provide an additional technical benefit of improving a reproducibility of a process between batches of substrates and between reaction chambers in multi-reaction chamber system.

In the multi-reaction chamber system, each reaction chamber may be connected to a power source (e.g., a RF power generator) and a matching network. For instance, a first reaction chamber may be connected to a first power source and a first matching network, and a second reaction chamber may be connected to a second power source and a second matching network.

A film may be formed on a substrate loaded in each reaction chamber by supplying a source gas as a first gas, a reactant as a second gas, and a third gas comprising a hydrogen to the reaction chamber. A power may be applied to each reaction chamber from each power source while supplying the second gas and the third gas.

In a conventional multi-reaction chamber system, an impedance matching may be carried out at fixed frequency mode in each reaction chamber. That is, a power frequency may be fixed and VVCs may move to match the impedance between the power source and the reaction chamber.

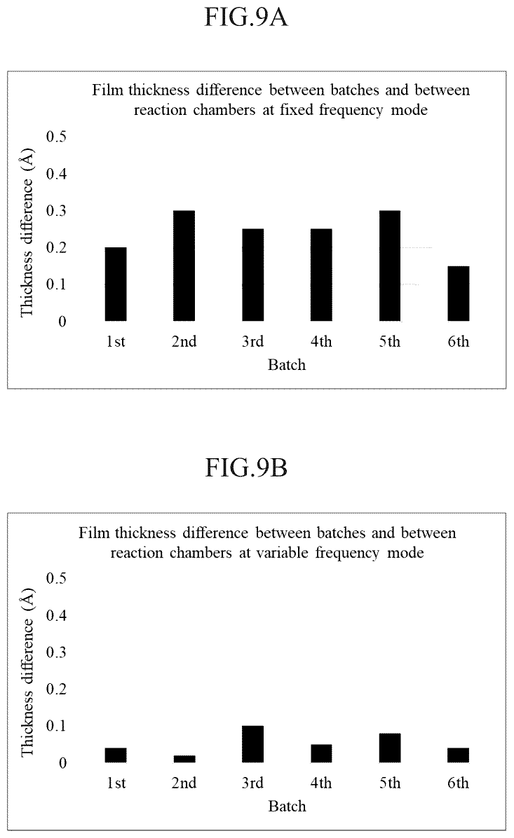

In the fixed frequency mode, mechanical and physical movements of VVCs may cause matching time difference between reaction chambers, resulting in low reproducibility of a process therebetween as shown in FIG. 9A.

FIG. 9A illustrates film thickness differences between batches and between reaction chambers in the same batch at fixed frequency mode. In FIG. 9A, 6 batches of substrates may be processed in the first reaction chamber and the second reaction chamber. A one batch of substrate may comprise 25 substrates. The film may be a TiN film formed by the method of the disclosure.

When compared a film thickness difference between batches (i.e., from the first batch to the sixth batch), the film thickness difference may be about 0.15Å (e.g., about 0.3 Å in the second batch and about 0.15Å in the sixth batch). And the film thickness difference between reaction chambers in the same batch may range from about 0.15Å to about 0.3Å (e.g., about 0.15Å in the sixth batch and about 0.3Å in the second batch).

In a multi-reaction chamber system according to an embodiment of the disclosure, an impedance matching may be carried out at variable frequency mode in each reaction chamber. That is, a power frequency may vary by a firmware or an algorithm embedded in the power source while fixing a position of VVCs in the matching network to match the impedance between a power source and a reaction chamber.

FIG. 9B illustrates film thickness differences between batches and between reaction chambers in the same batch at variable frequency mode. In FIG. 9B, 6 batches of substrates may be processed in the first reaction chamber and the second reaction chamber. A one batch of substrates may comprise 25 substrates. The film may be a TiN film formed by the method of the disclosure.

When compared a film thickness difference between batches (i.e., from the first batch to the sixth batch), the film thickness difference may below about 0.1Å (e.g., about 0.02Å in the second batch and about 0.1 Å in the third batch), lower than in the fixed frequency mode. And the film thickness difference between reaction chambers in the same batch may below about 0.1Å (e.g., about 0.02Å in the second batch and about 0.1Å in the third batch), lower than in the fixed frequency mode. That is, a fast matching may reduce a matching time difference between reaction chambers, resulting in improving a reproducibility of a process between batches and between reaction chambers.

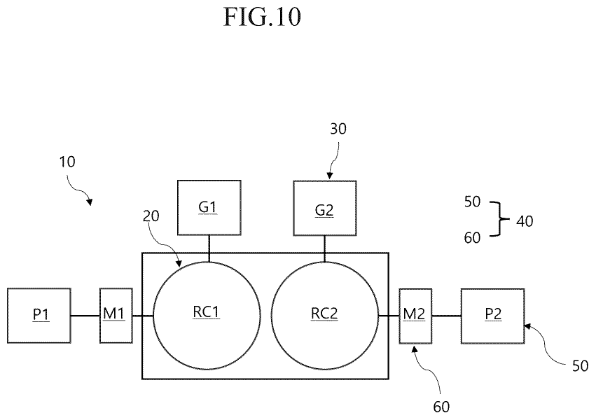

FIG. 10 illustrates a multi-reaction chamber system 10 according to the disclosure.

In FIG. 10, the multi-reaction chamber system 10 may comprise a reaction chamber unit 20 to process a substrate, a gas supply unit 30 to supply a gas to the reaction chamber unit 20 and a power supply unit 40 to apply a power to the reaction chamber unit 20.

The reaction chamber unit 20 may comprise a plurality of reaction chamber (i.e., a first reaction chamber RC1 and a second reaction chamber RC2). But the number of the reaction chamber may not be limited thereto. In other embodiment, the reaction chamber unit 20 may further comprise a third reaction chamber and a fourth reaction chamber (not shown herein).

The gas supply unit 30 may comprise a first gas supply unit G1 to supply a gas to the first reaction chamber RC1 and a second gas supply unit G2 to supply a gas to the second reaction chamber RC2.

The power supply unit 40 may comprise a power source 50 (e.g., a RF power generator) to generate a power and a matching network 60 to match an impedance between the power source 50 and the reaction chamber unit 20. The power source 50 may comprise a first power source P1 to apply a power to the first reaction chamber RC1 and a second power source P2 to apply a power to the second reaction chamber RC2.

The matching network 60 may comprise a first matching network M1 to match an impedance between the first power source P1 and the first reaction chamber RC1 and a second matching network M2 to match an impedance between the second power source P2 and the second reaction chamber RC2.

The power source 50 may be provided with a firm ware or an algorithm to vary a frequency of the power.

The matching network 60 may comprise VVCs (Vacuum Variable Capacitors). The VVCs may mechanically move to find the optimal matching position.

In one embodiment according to the disclosure, a first gas as a source gas and a second gas as a reactant may be supplied to the reaction chamber unit 20 to form a film on a substrate. The second gas may be activated by a power applied to the reaction chamber. When the power is applied, a matching may be performed between the power source 50 and the reaction chamber unit 20 by varying the frequency of the power by the firmware embedded in the power source, not moving the VVCs in the matching network 60.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

1. A method of forming a film on a patterned substrate, the method comprising:
providing the patterned substrate to a reaction chamber;
supplying a first gas to the reaction chamber;
supplying a second gas to the reaction chamber; and
applying a power to the reaction chamber,
wherein the power has a frequency that is variable,
wherein the second gas is activated by the power, and
wherein the activated second gas reacts with the first gas to form a film on the patterned substrate.

2. The method of claim 1, wherein the film comprises an amorphous titanium nitride.

3. The method of claim 2, wherein the amorphous titanium nitride film further comprises impurities at a level of 25% or less.

4. The method of claim 3, wherein the impurities comprise at least one of an oxygen, a carbon, or a mixture thereof.

5. The method of claim 2, wherein the film is a spacer film.

6. The method of claim 1, wherein a reflect power of 5W or less is generated during applying the power to the reaction chamber.

7. The method of claim 1, wherein the first gas comprises a titanium-containing gas.

8. The method of claim 7, wherein the first gas comprises at least one of tetrakis-dimethylamino titanium (Ti[N(CH₃)₂]₄, TDMAT), tetrakis-diethylamido titanium, ([(C₂H₅)₂N]₄Ti, TDEAT), tetrakis-ethylmethylamino titanium (Ti[(CH₃C₂H₅)N]₄, TEMAT), titanium isopropoxide (Ti[OCH(CH₃)₂], TTIP), titanium chloride (TiCl₄), a derivative thereof, or a mixture thereof.

9. The method of claim 1, wherein the second gas comprises a nitrogen-containing gas.

10. The method of claim 9, wherein the second gas comprises at least one of N₂, NH₃, NH₄, N₂H₂, N₂H₄, or a mixture thereof.

11. The method of claim 1, further comprising supplying a third gas to the reaction chamber and activating the second gas and the third gas simultaneously by the power.

12. The method of claim 11, wherein the method is repeated a plurality of times.

13. The method of claim 1, further comprising treating the film by supplying a third gas to the reaction chamber and activating the third gas by the power after forming the film, wherein a frequency of the power is variable frequency.

14. The method of claim 13, treating the film and forming the film are repeated a plurality of times respectively, and a super cycle comprising treating the film and forming the film are repeated a plurality of times.

15. The method of claim 11, wherein the third gas comprises a hydrogen-containing gas.

16. The method of claim 15, wherein the third gas comprises at least one of a hydrogen, an atomic hydrogen, or a mixture thereof.

17. The method of claim 1, wherein the method of forming the film is carried out at between about 100° C. and about 250° C., or between about 150° C. and about 200°° C.

18. The method of claim 1, wherein the power of between about 200W and about 500W, or between about 250W and about 450W is applied to the reaction chamber.

19. A method of patterning a substrate, the method comprising;
providing a substrate to a reaction chamber;
forming a first film on the substrate;
forming a second film on the first film;
patterning the second film;
forming a third film on the second film;
removing the third film selectively;
removing the second film;
removing the first film selectively; and
removing the third film, wherein the first film comprises a carbon-containing material, the second film comprises a silicon-containing material, and the third film comprises a titanium-containing material.

20. The method of claim 19, wherein the first film comprises an amorphous carbon and the second film comprises an amorphous silicon.

21. The method of claim 19, wherein removing the third film selectively is carried out by an etch back.

22. The method of claim 19, wherein removing the second film and removing the first film selectively are carried out by a selective etch.

23. The method of claim 19, wherein removing the third film is carried out by at least one of ashing or stripping.

24. The method of claim 19, wherein the third film comprises an amorphous titanium nitride.

25. The method of claim 19, wherein the forming the third film on the second film is performed by the method of claim 1.

26. An apparatus performing the method of claim 1, comprising;
a reaction chamber unit to process a substrate;
a gas supply unit to supply a first gas as a source gas and a second gas as a reactant to the reaction chamber unit to form a film on the substrate; and
a power supply unit comprising a power source and a matching network to apply a power to the reaction chamber unit,
wherein the second gas is activated by a power applied to the reaction chamber unit and a matching is performed between the power source and the reaction chamber unit by varying a frequency of the power while applying the power to the reaction chamber unit.
